(19) United States
(12) Patent Application Publication
(10) Pub. No.: US 2025/0385022 A1
(43) Pub. Date: Dec. 18, 2025

(54) WIRE HARNESS

(71) Applicant: Proterial, Ltd., Tokyo (JP)

(72) Inventors: Hiroshi YAMADA, Tokyo (JP); Naoto MAEDA, Tokyo (JP); Tomoaki SUZUKI, Tokyo (JP); Akitoshi FUJIMORI, Tokyo (JP)

(21) Appl. No.: 19/233,804

(22) Filed: Jun. 10, 2025

(30) Foreign Application Priority Data
Jun. 17, 2024 (JP) 2024-097613

(51) Int. Cl. H01B 7/00; B60R 16/02; H01B 7/18; H01B 9/02; H05K 9/00

(52) U.S. Cl. CPC H01B 7/0045; B60R 16/0215; H01B 7/18; H01B 9/025; H01B 9/028; H05K 9/0098

(57) ABSTRACT

A wire harness includes a plurality of electric wires, a sheath that covers a portion of the plurality of electric wires in a longitudinal direction, a shield conductor that is interposed between the plurality of electric wires and the sheath and covers all of the plurality of electric wires, a ground wire connected to the shield conductor, and a covering body that covers an outer circumference of the shield conductor and the plurality of electric wires extending out of an end of the sheath, as well as the end of the sheath and a portion of the ground wire, wherein extending directions of the plurality of electric wires and the ground wire from the covering body are fixed by the covering body.

### CROSS-REFERENCE TO RELATED APPLICATIONS

The present application is based on Japanese patent application No. 2024-097613 filed on Jun. 17, 2024, the entire contents of which are incorporated herein by reference.

### TECHNICAL FIELD

The present invention relates to a wire harness.

### BACKGROUND OF THE INVENTION

Electric wires described in Patent Literatures 1 and 2 are known as conventional electric wires having a shield for noise suppression.

The shielded wire described in Patent Literature 1 includes an insulated wire in which a conductor is covered with an insulating sheath, a braided wire formed by braiding metal strands into a cylindrical shape, and a protective jacket that surrounds the outside of the braided wire. The braided wire includes a shield portion into which the insulated electric wire is inserted and which is surrounded by the protective jacket, and a ground wire that is exposed from a tip of the protective jacket and extends toward the outside. The ground wire is surrounded by an insulating resin tube over substantially the entire length and has an end to which a grounding terminal is attached.

The composite electrical wire described in Patent Literature 2 includes a shielded wire that includes plural insulated wires and a film-shaped metal shield covering the outer side of the plural insulated wires and an insulating sheath covering the outer side of the metal shield, a lead wire electrically connected to the metal shield, and a fixing member which is a ring-shaped crimping member to fix the lead wire to the shielded wire. The metal shield has an inner portion covered with the sheath, and a folded back portion folded back to the outside of the sheath. A terminal is attached to one end of the lead wire, and the other end of the lead wire is connected to ground potential. The fixing member presses the terminal attached to the lead wire, as well as the folded back portion of the metal shield, against the sheath of the shielded wire.
Citation List Patent Literature 1: JP2023-115654A
Patent Literature 2: JP2023-66548A

### SUMMARY OF THE INVENTION

When a terminal portion of the electric wire described in Patent Literature 1 or 2 is arranged, e.g., inside a wheel well of an automobile, moisture is likely to enter the inside through an opening of the protective jacket or sheath. For this reason, the opening of the protective jacket or sheath, as well as the insulated wire, the braided wire and the folded back portion of the metal shield, or a portion of the lead wire, could be covered with a cover portion formed, e.g., by winding a vinyl tape so that the insulated wire and the ground wire or lead wire extend in the same direction from the cover portion. This configuration, however, increases the difficulty of routing since the connection point of the insulated electric wire is generally different from the connection point of the ground wire or lead wire. Therefore, it is an object of the invention to enhance the ease of installation and waterproof performance of a wire harness.

To achieve the above object, one aspect of the invention provides a wire harness comprising;
a plurality of electric wires;
a sheath that covers a portion of the plurality of electric wires in a longitudinal direction;
a shield conductor that is interposed between the plurality of electric wires and the sheath and covers all of the plurality of electric wires;
a ground wire connected to the shield conductor; and
a covering body that covers an outer circumference of the shield conductor and the plurality of electric wires extending out of an end of the sheath, as well as the end of the sheath and a portion of the ground wire,
wherein the shield conductor collectively covers all the plurality of electric wires that are covered with the sheath, and
wherein extending directions of the plurality of electric wires and the ground wire are fixed by the covering body.

### Advantageous Effects of the Invention

According to the invention, it is possible to enhance the ease of installation and waterproof performance of a wire harness.

### BRIEF DESCRIPTION OF DRAWINGS

FIGS. 1A and 1B are configuration diagrams illustrating one end portion of a wire harness in an embodiment of the present invention.

FIGS. 2A and 2B are perspective views showing a portion of the wire harness.

FIG. 3A is a cross-sectional view taken along line A-A in FIG. 1A.

FIG. 3B is a cross-sectional view taken along line B-B in FIG. 1A.

FIG. 3C is a cross-sectional view taken along line C-C in FIG. 1A.

FIGS. 4A to 4E are explanatory diagrams illustrating an example of a wire harness manufacturing procedure.

FIG. 5 is an explanatory diagram illustrating an example of how the wire harness is used.

FIG. 6 is a perspective view showing a portion of the wire harness in Modification 1.

FIG. 7 is a perspective view showing a portion of the wire harness in Modification 2.

FIG. 8A is a configuration diagram illustrating one end portion of the wire harness in Modification 3.

FIG. 8B is a configuration diagram in which the outline of a covering body of the wire harness shown in FIG. 8A is indicated by a phantom line.

FIG. 9 is a cross-sectional view taken along line D-D in FIG. 8A.

### DETAILED DESCRIPTION OF THE INVENTION

### Embodiment

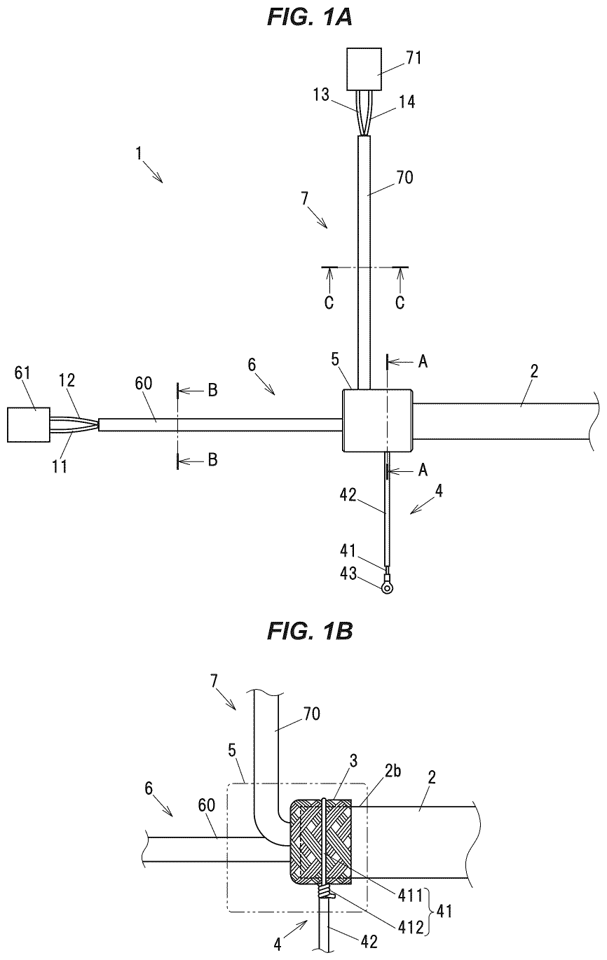

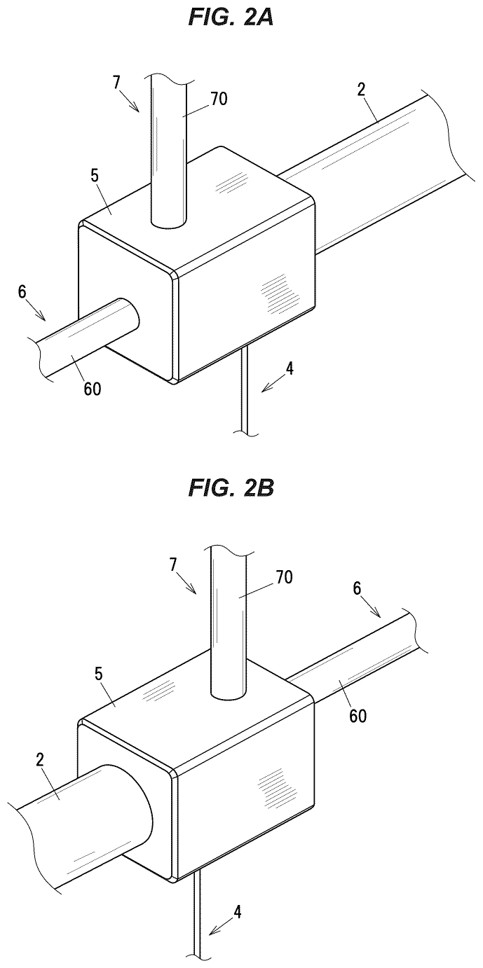

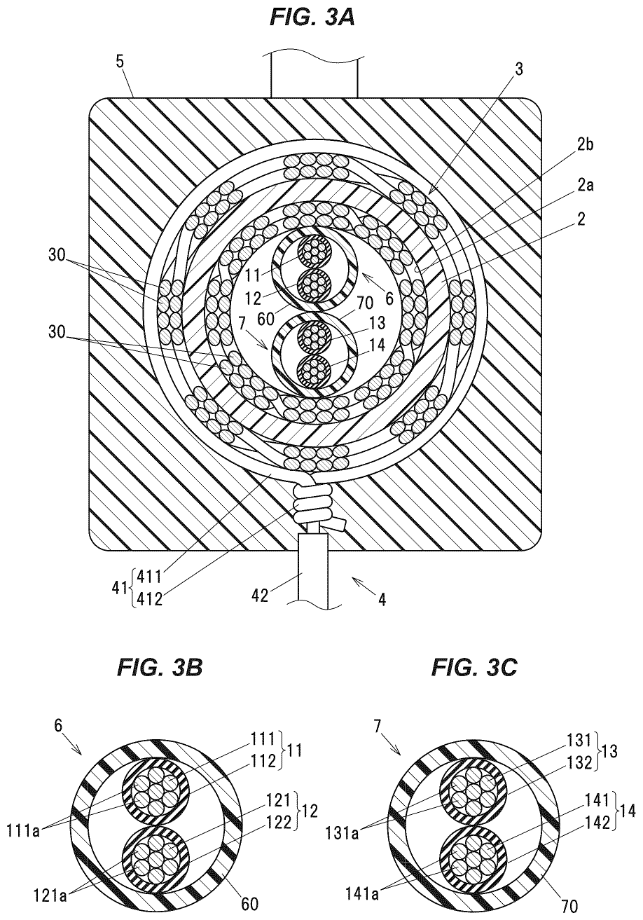

FIGS. 1A and 1B are configuration diagrams illustrating one end portion of a wire harness 1 in an embodiment of the invention. FIGS. 2A and 2B are perspective views of a portion of the wire harness 1 as viewed respectively from different directions. FIG. 3A is a cross-sectional view taken along line A-A in FIG. 1A. FIG. 3B is a cross-sectional view taken along line B-B in FIG. 1A. FIG. 3C is a cross-sectional view taken along line C-C in FIG. 1A. The wire harness 1 is, e.g., wired in a vehicle in such a manner that one end portion, which is shown in FIG. 1A, is arranged inside a wheel well.

The wire harness 1 includes plural electric wires 11 to 14, a sheath 2 covering a portion of the plural electric wires 11 to 14 in a longitudinal direction, a shield conductor 3 that is interposed between the plural electric wires 11 to 14 and the sheath 2 and covers the plural electric wires 11 to 14, a ground wire 4 connected to the shield conductor 3, and a covering body 5 that covers an outer circumference of the shield conductor 3 and the plurality of electric wires 11 to 14 extending out of an end of the sheath 2, as well as the end of the sheath 2 and a portion of the ground wire 4. In FIG. 1B, the outline of the covering body 5 is indicated by a phantom line, and the components thereinside are indicated by solid lines.

In the present embodiment, the wire harness 1 has four electric wires 11 to 14. Of those, two electric wires 11 and 12 are covered with a first inner sheath 60, and the other two electric wires 13 and 14 are covered with a second inner sheath 70. Each of the electric wires 11 to 14 is an insulated wire in which a core wire 111, 121, 131, 141 is covered with an insulation 112, 122, 132, 142, as shown in FIGS. 3A to 3C. Each of the core wires 111, 121, 131, 141 is a stranded wire formed by twisting plural conductor strands 111a, 121a, 131a, or 141a together. However, the core wires 111, 121, 131, and 141 are not limited to the stranded wires, and may be solid wires. In addition, the outer diameters of the electric wires 11 to 14 are the same in the example shown in FIG. 3, but may be different. In addition, the first inner sheath 60 and the second inner sheath 70 have a tubular hollow structure in the example shown in FIG. 3, but not limited thereto and may have a solid (non-hollow) structure.

The first inner sheath 60 and the electric wires 11, 12 constitute a first cable 6. The second inner sheath 70 and the electric wires 13, 14 constitute a second cable 7. That is, the wire harness 1 has the first cable 6 and the second cable 7 and is configured such that a portion of the first cable 6 and the second cable 7 in the longitudinal direction, as well as the shield conductor 3, is covered with the sheath 2. The first cable 6 and the second cable 7 branch off inside the covering body 5 and are respectively connected to different connection targets.

A portion of the first inner sheath 60 and the second inner sheath 70 extending out of the sheath 2 is covered with the covering body 5. At an end of the first cable 6, the electric wires 11, 12 extend out of the first inner sheath 60 and a first connector 61 is attached to the electric wires 11, 12 which extend out. Likewise, at an end of the second cable 7, the electric wires 13, 14 extend out of the second inner sheath 70 and a second connector 71 is attached to the electric wires 13, 14 which extend out.

In the present embodiment, the shield conductor 3 is composed of a wire braid formed by braiding plural shield strands 30 in a grid pattern. Alternatively, the shield conductor 3 may be composed of plural shield wires, or a conductive tape (conductive adhesive tape), spirally wound around the plural electric wires 11 to 14, the first inner sheath 60 and the second inner sheath 70. The shield conductor 3 collectively covers all the electric wires 11 to 14 which are covered with the sheath 2, to electromagnetically shield the electric wires 11 to 14.

The shield conductor 3 has an end portion extending out of the sheath 2, and the portion extending out of the sheath 2 is folded back onto the outer circumference of the sheath 2 inside the covering body 5. Thus, at the end of the sheath 2, the shield conductor 3 is in contact with an inner circumferential surface 2a and an outer circumferential surface 2b of the sheath 2, as shown in FIG. 3A. The portion of the shield conductor 3 folded back onto the outer circumference of the sheath 2 is entirely covered with the covering body 5. The covering body 5 is in tight contact with all around the outer circumferential surface 2b of the sheath 2 at a portion not covered by the shield conductor 3.

The ground wire 4 has a ground wire conductor 41, an insulation 42 covering the ground wire conductor 41, and a grounding terminal 43. A normal insulated wire may be used as the ground wire 4, or the ground wire 4 may be formed by covering the ground wire conductor 41 with an insulating tube. At one end of the ground wire 4, a portion of the insulation 42 is covered with the covering body 5. At the other end of the ground wire 4, the ground wire conductor 41 extends out of the insulation 42 and the grounding terminal 43 is connected to a tip of the portion which extends out. The ground wire conductor 41 is composed of, e.g., a solid wire having a circular cross-sectional shape, but may be a stranded wire formed by twisting plural strands in a spiral manner. The ground wire conductor 41 is connected to ground potential through the grounding terminal 43. The ground wire conductor 41 may be connected to the ground potential by a separate wire connected through a joint terminal or a connector, or the like.

The ground wire conductor 41 extending out of an end of the insulation 42 opposite the grounding terminal 43 is connected to the portion of the shield conductor 3 that is folded back onto the outer circumference of the sheath 2. In the present embodiment, the ground wire conductor 41 is wound on the outer circumference of the folded back portion of the shield conductor 3. In more particular, the ground wire conductor 41 extending out of the insulation 42 at the portion covered with the covering body 5 has a wound portion 411 wound around the outer circumference of the folded back portion of the shield conductor 3, and a twisted portion 412 twisted together.

The wound portion 411 is wound at least once around the outer circumference of the folded back portion of the shield conductor 3. The portion of the shield conductor 3 folded back onto the outer circumference of the sheath 2 is tightened toward the sheath 2 by the wound portion 411. Two longitudinal ends of the portion of the ground wire conductor 41 extending out of the insulation 42 on the side opposite to the grounding terminal 43 are twisted together, and the twisted portion 412 is thereby formed. The wound portion 411 is formed of a portion located between the two longitudinal ends. To prevent the twisted portion 412 from unraveling, the twisted portion 412 may be fixed with adhesive, solder, a heat shrink tube, or the like.

In the present embodiment, the covering body 5 has a rectangular parallelepiped shape as shown in FIGS. 2A and 2B. In addition, in the present embodiment, the covering body 5 is composed of a resin molded body. When molding the covering body 5, an end portion of the shield conductor 3 is folded back onto the outer circumference of the sheath 2 and the ground wire conductor 41 is connected to the shield conductor 3, and in this state, the sheath 2, the first cable 6, the second cable 7 and the ground wire 4 are set in a mold in a predetermined position as shown in FIG. 1B and the mold is clamped shut, and a molding resin melted by heat is injected into the mold. Then, the mold is opened after solidification of the molding resin, thereby obtaining the wire harness 1 in which the sheath 2, the first cable 6, the second cable 7, and the ground wire 4 are each partially covered with the covering body 5.

The extending directions of the electric wires 11 to 14 and the ground wire 4 from the covering body 5 are fixed by the covering body 5. In the present embodiment, the electric wires 11, 12 of the first cable 6, as well as the first inner sheath 60, extend from the covering body 5 in parallel to the portion of the sheath 2 covered with the covering body 5. The electric wires 13, 14 of the second cable 7, as well as the second inner sheath 70, extend perpendicular to the portion of the sheath 2 covered with the covering body 5. The ground wire 4 extends perpendicular to the portion of the sheath 2 covered with the covering body 5 in a direction opposite to the extending direction of the second cable 7.

The extending directions of the first cable 6 and the second cable 7 from the covering body 5 are directions toward the respective connection targets of the first cable 6 and the second cable 7. The extending direction of the ground wire 4 does not necessarily need to be a direction toward the point where the grounding terminal 43 is fixed, but it is a direction in which at least routing of the ground wire 4 is not difficult. This enhances the ease of installation the wire harness 1.

The covering body 5 serves to guide the electric wires 11, 12 of the first cable 6, the electric wires 13, 14 of the second cable 7, and the ground wire 4 in directions facilitating respective routings, and also serves to suppress ingress of moisture into the inside of the sheath 2 and enhance the waterproof performance. To enhance the waterproof performance, the sheath 2, the first inner sheath 60 and the second inner sheath 70 are desirably made of the same type of resin as the covering body 5. As such a resin, it is possible to suitably use, e.g., urethane. When the same type of resin as the covering body 5 is used as the material of the sheath 2, the first inner sheath 60 and the second inner sheath 70, compatibility due to heat during molding of the covering body 5 is enhanced and the waterproof performance are improved. The insulation 42 of the ground wire 4 may also be made of the same type of resin as the covering body 5.

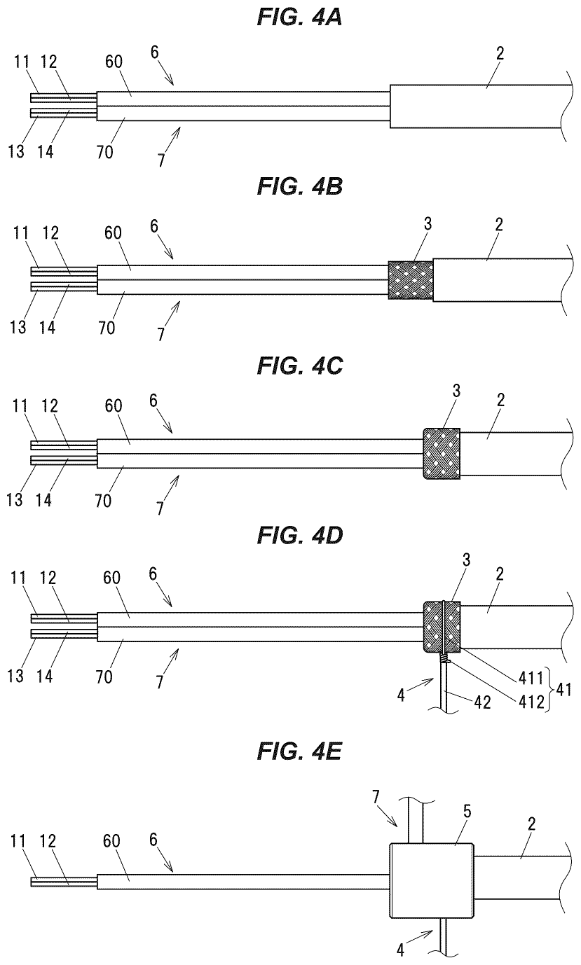

FIGS. 4A to 4C are explanatory diagrams illustrating an example procedure when manufacturing the wire harness 1. The method for manufacturing the wire harness 1 includes a first step of exposing the first inner sheath 60 of the first cable 6 and the second inner sheath 70 of the second cable 7 by removing a predetermined length of the sheath 2 and the shield conductor 3 (see FIG. 4A), a second step of exposing the shield conductor 3 by further removing an end portion of the sheath 2 (see FIG. 4B), a third step in which the shield conductor 3 exposed in the second step is folded back onto the outer circumference of the sheath 2 (see FIG. 4C), a fourth step in which the ground wire conductor 41 is wound around the outer circumference of the folded back portion of the shield conductor 3 to form the wound portion 411 and the twisted portion 412 (see FIG. 4D), and a fifth step of forming the covering body 5 (see FIG. 4E). After that, the first connector 61 is attached to the ends of the electric wires 11 and 12, the second connector 71 is attached to the ends of the electric wires 13 and 14, and the wire harness 1 is thereby obtained. In this regard, the first connector 61 and the second connector 71 may be attached at any time after the first step.

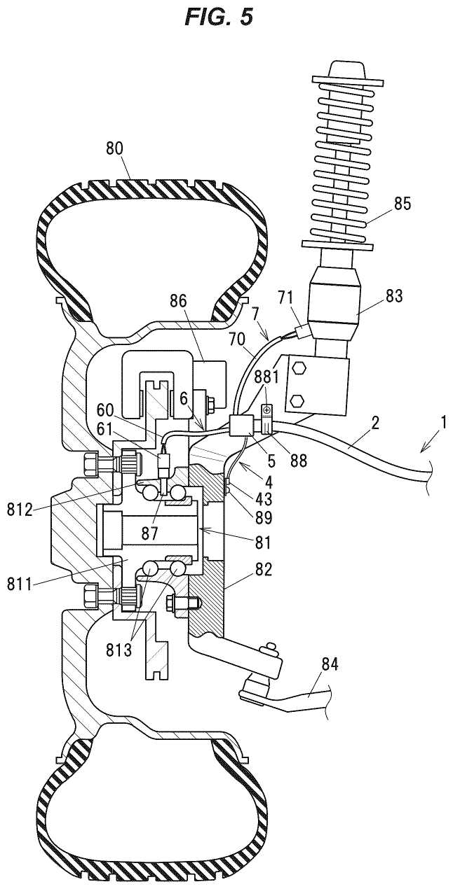

FIG. 5 is an explanatory diagram illustrating an example of how the wire harness 1 is used. The up-and-down direction in FIG. 5 corresponds to up and down in the vertical direction of a vehicle. FIG. 5 shows a wheel 80 of the vehicle, a hub unit 81 rotatably supporting the wheel 80, a knuckle 82 to which the hub unit 81 is attached, a variable damping-force damper 83 and a lower arm 84 that are connected to the knuckle 82, a suspension spring 85 arranged around the outer circumference of the variable damping-force damper 83, an electric parking brake device 86, and a wheel speed sensor 87 to detect a rotation speed of the wheel 80. The hub unit 81 has a hub ring 811 that rotates together with the wheel 80, an outer ring 812 fixed to the knuckle 82, and plural rolling elements 813 arranged between the hub ring 811 and the outer ring 812, and the wheel speed sensor 87 detects the rotational speed of the hub ring 811 relative to the outer ring 812.

In the example shown in FIG. 5, the first connector 61 provided at one end of the first cable 6 is attached to the wheel speed sensor 87, and the second connector 71 provided at one end of the second cable 7 is attached to the variable damping-force damper 83. The other end of the first cable 6 is connected to a brake control device that controls a braking force acting on the wheel 80 to suppress locking of the wheel 80. The other end of the second cable 7 is connected to a damping force control device that controls a damping force of the variable damping-force damper 83 according to the driving state of the vehicle.

That is, in the example of how the wire harness 1 is used shown in FIG. 5, the first cable 6 serves as an ABS (Antilock brake system) cable and the second cable 7 serves as an ADS (Active damper suspension) cable. Alternatively, the second connector 71 may be connected to the electric parking brake device 86, and the electric wires 13, 14 of the second cable 7 may be used as control signal lines or power lines of the electric parking brake device 86. In this case, the second cable 7 serves as an EPB (Electric Parking Brake) cable.

The sheath 2 is supported near the covering body 5 by a support fixture 88 fixed to the knuckle 82. The ground wire 4 extends vertically downward from the covering body 5, and the grounding terminal 43 is fixed to the knuckle 82 by a bolt 89. The knuckle 82 is electrically connected to the vehicle body and is grounded.

Since the first cable 6, the second cable 7 and the ground wire 4 extend respectively in different directions from the covering body 5 as described above, the ease of installation the wiring harness 1 is enhanced and it is also possible to reduce the length of the first cable 6 between the wheel speed sensor 87, which is the connection target of the first cable 6, and the covering body 5 and to reduce the length of the second cable 7 between the variable damping-force damper 83, which is the connection target of the second cable 7, and the covering body 5.

In this regard, since the ground wire 4 can be bent with a smaller radius of curvature than the first cable 6 and the second cable 7, connection of the grounding terminal 43 to the knuckle 82 does not necessarily need to be below the covering body 5 by the bolt 89, and the grounding terminal 43 may be fixed, e.g., by a bolt 881 that fixes the support fixture 88 to the knuckle 82. However, when wiring the ground wire 4 so as to extend out of the covering body 5 toward the portion where the grounding terminal 43 is fixed, it is possible to fix the grounding terminal 43 without bending the ground wire 4 with a small radius of curvature, which further enhances the ease of installation. In addition, the object to which the sheath 2 and the ground wire 4 are fixed is not limited to the knuckle 82 and may be, e.g., a component of a suspension device that suspends the wheel 80 on the vehicle body.

### Modification 1

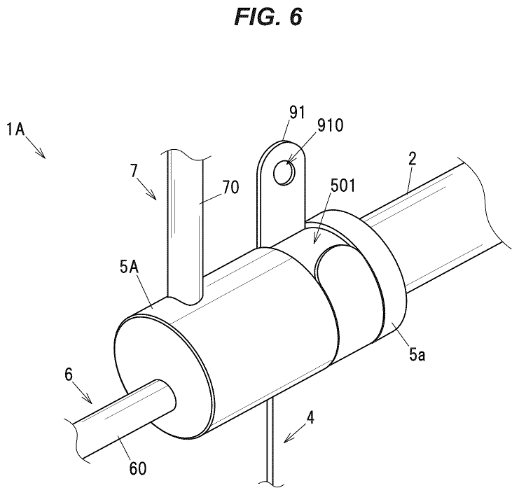

Modification 1 of the embodiment will be described with reference to FIG. 6. FIG. 6 is a perspective view showing a portion of a wire harness 1A in Modification 1 of the embodiment. In the above embodiment, the case where the covering body 5 has a rectangular parallelepiped shape has been described. In contrast, in Modification 1 shown in FIG. 6, a covering body 5A has a cylindrical shape, and a metal bracket 91 is fixed to the covering body 5A. The bracket 91 is tightly wound and fixed in a groove 501 formed on an outer circumferential surface 5a of the covering body 5A, and is not in contact with any members other than the covering body 5A, such as the sheath 2 or the shield conductor 3. The bracket 91 has a bolt insertion hole 910 through which a bolt to fix the bracket 91 to a fixing target is inserted. The bolt insertion hole 910 may be provided with a metal bushing for screw fastening. The rest of the configuration, material, and functions of the covering body 5A are the same as those of the covering body 5 in the embodiment described above. The extending direction of the bracket 91 is a direction parallel to the extending direction of the second cable 7 in FIG. 6 but is not limited thereto. The extending direction of the bracket 91 may be, e.g., a direction orthogonal to the first cable 6 and to the second cable 7.

### Modification 2

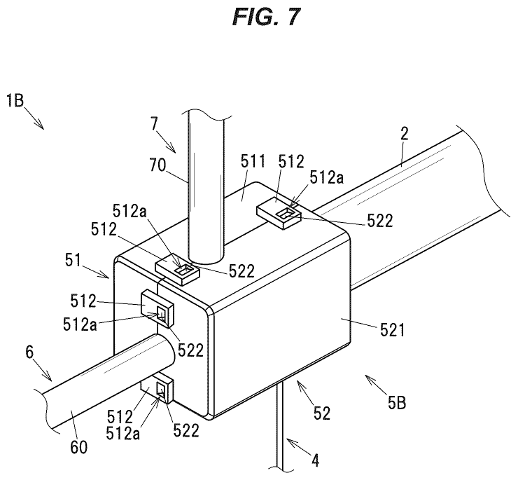

Modification 2 of the embodiment will be described with reference to FIG. 7. FIG. 7 is a perspective view showing a portion of a wire harness 1B in Modification 2 of the embodiment. In the above embodiment, the case where the covering body 5 is a resin molded body has been described. In contrast, in Modification 2 shown in FIG. 7, a covering body 5B is a cover having a pair of cover members 51 and 52. The cover members 51 and 52 are made of a resin and formed by injection molding.

The cover member 51, which is one of the pair of cover members 51, 52, integrally has a main body portion 511 and plural locking pieces 512. The cover member 52, which is the other of the pair, integrally has a main body portion 521 and plural locking protrusions 522. The plural locking pieces 512 of the one cover member 51 each have a locking hole 512a, and by fitting the locking protrusions 522 to the locking holes 512a, the locking protrusions 522 are locked to the locking pieces 512 and the pair of cover members 51 and 52 are assembled together.

The respective main body portions 511, 521 of the pair of cover members 51, 52 have a shape obtained by halving the covering body 5 of the embodiment described above, and the first cable 6, the second cable 7 and the ground wire 4 are sandwiched and held between the main body portion 511 of the one cover member 51 and the main body portion 521 of the other cover member 52. The extending directions of the first cable 6, the second cable 7 and the ground wire 4 from the covering body 5B are fixed by the covering body 5B. The portion of the shield conductor 3 folded back onto the outer circumference of the sheath 2 is entirely covered with the covering body 5B, and the insulation 42 of the ground wire 4 is partially covered with the covering body 5B.

The pair of cover members 51, 52 is not limited to having the snap-fit structure described above, and may be fixed to each other by, e.g., bolts and nuts or may be integrated by ultrasonic welding or laser welding. Furthermore, the cover members 51 and 52 may be coupled by a hinge unit.

### Modification 3

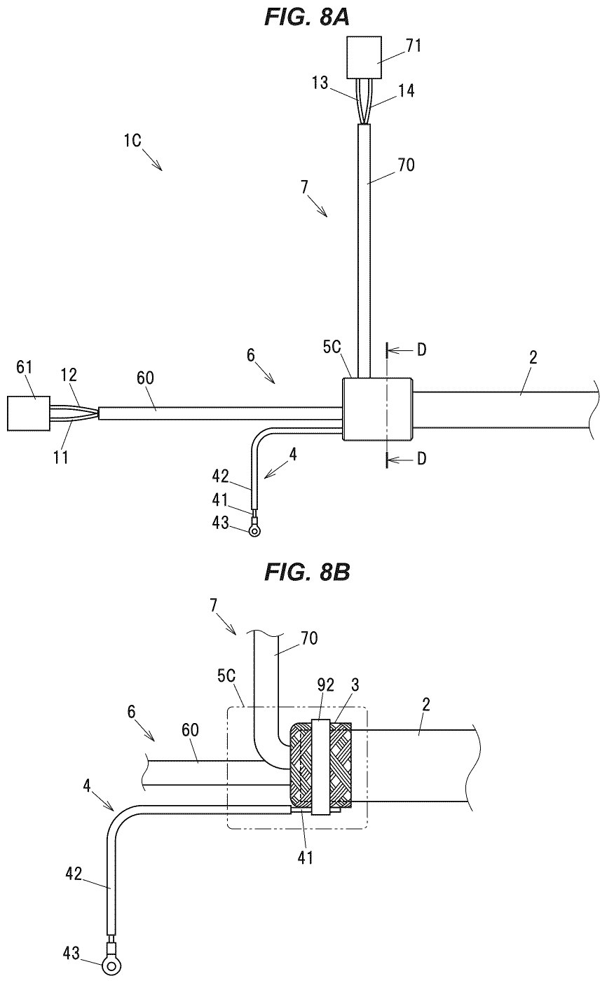

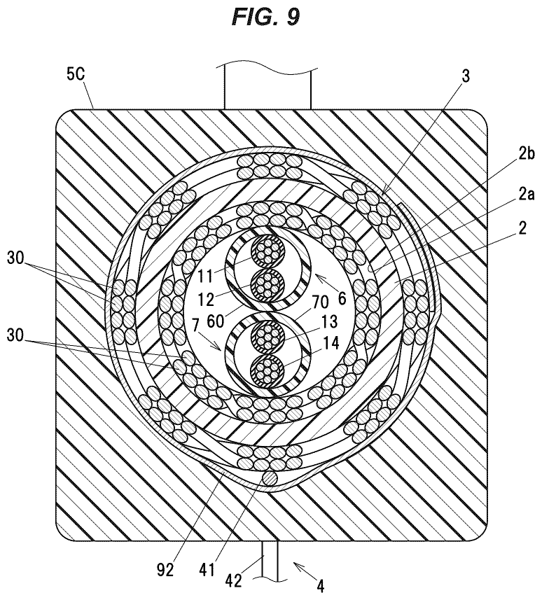

Modification 3 of the embodiment will be described with reference to FIGS. 8 and 9. FIG. 8A is a configuration diagram illustrating one end portion of a wire harness 1C in Modification 3. FIG. 8B is a configuration diagram in which the outline of a covering body 5C of the wire harness 1C is indicated by a phantom line and the components thereinside are indicated by solid lines. FIG. 9 is a cross-sectional view taken along line D-D in FIG. 8A.

In the above embodiment, the case where the ground wire conductor 41 is wound around the outer circumference of the folded back portion of the shield conductor 3 has been described. In contrast, in Modification 3, a portion of the ground wire conductor 41 is placed on the outer circumference of the folded back portion of the shield conductor 3 and is fixed to the shield conductor 3 by a band-shaped fixing member 92. The fixing member 92 is, e.g., a conductive tape (conductive adhesive tape) and surrounds the entire circumference of the shield conductor 3. The ground wire conductor 41 is sandwiched between the fixing member 92 and the shield conductor 3 and is in contact with the shield conductor 3.

In addition, the case where the ground wire 4 extends in a direction opposite to the extending direction of the second cable 7 has been described in the above embodiment, but the ground wire 4 extends out of the covering body 5C in parallel to the first cable 6 in Modification 3. To ensure the waterproof performance, a sealing member such as a packing is preferably arranged between the pair of cover members 51, 52. A sealing member such as a packing is preferably arranged also between the pair of cover members 51, 52 and the sheath 2, the first inner sheath 60, the second inner sheath 70, the ground wire 4.

### SUMMARY OF THE EMBODIMENT

Technical ideas understood from the embodiment will be described below citing the reference signs, etc., used for the embodiment. However, each reference sign described below is not intended to limit the constituent elements in the claims to the members, etc., specifically described in the embodiment.

According to the first feature, a wire harness 1, 1A, 1B, 1C comprises a plurality of electric wires 11 to 14; a sheath 2 that covers a portion of the plurality of electric wires 11 to 14 in a longitudinal direction; a shield conductor 3 that is interposed between the plurality of electric wires 11 to 14 and the sheath 2 and covers all of the plurality of electric wires 11 to 14; a ground wire 4 connected to the shield conductor 3; and a covering body 5, 5A, 5B, 5C that covers an outer circumference of the shield conductor 3 and the plurality of electric wires 11 to 14 extending out of an end of the sheath 2, as well as the end of the sheath 2 and a portion of the ground wire 4, wherein extending directions of the plurality of electric wires 11 to 14 and the ground wire 4 from the covering body 5, 5A, 5B, 5C are fixed by the covering body 5, 5A, 5B, 5C.

According to the second feature, in the wire harness 1, 1A, 1B, 1C as described in the first feature, the ground wire 4 comprises a ground wire conductor 41 and an insulation 42 covering the ground wire conductor 41, wherein a portion of the insulation 42 is covered with the covering body 5, 5A, 5B, 5C on one end side of the ground wire 4, and wherein the ground wire conductor 41 extends out of the insulation 42 on the other end side of the ground wire 4.

According to the third feature, in the wire harness 1, 1A, 1B, 1C as described in the second feature, a portion of the shield conductor 3 extending out of the sheath 2 is folded back onto an outer circumference of the sheath 2 inside the covering body 5, 5A, 5B, 5C, and wherein the ground wire conductor 41 is connected to the folded back portion of the shield conductor 3.

According to the fourth feature, in the wire harness 1, 1A, 1B as described in the third feature, the ground wire conductor 41 is wound around an outer circumference of the folded back portion of the shield conductor 3.

According to the fifth feature, in the wire harness 1, 1A, 1B as described in the fourth feature, the ground wire conductor 41 comprises a wound portion 411 wound around the outer circumference of the folded back portion of the shield conductor 3, and a twisted portion 412 twisted together, and wherein the folded back portion of the shield conductor 3 is tightened by the wound portion 411.

According to the sixth feature, in the wire harness 1C as described in the third feature, a portion of the ground wire conductor 41 is placed on the outer circumference of the folded back portion of the shield conductor 3, and the portion of the ground wire conductor 41 is fixed to the shield conductor 3 by a fixing member 92.

According to the seventh feature, in the wire harness 1, 1A, 1B, 1C as described in any one of the first to sixth feature, the covering body 5, 5A, 5B, 5C comprises a resin molded body or a cover formed by combining a plurality of cover members 51, 52.

According to the eighth feature, in the wire harness 1A as described in the seventh feature, a metal bracket 91 is fixed to the covering body 5A.

Although the embodiment and modifications of the invention have been described, the invention according to claims is not to be limited to the embodiment and modifications described above. Further, please note that not all combinations of the features described in the embodiment and modifications are necessary to solve the problem of the invention. In addition, the invention can be appropriately modified and implemented without departing from the gist of the invention. For example, the following modifications are possible.

In the above embodiment, the case where the wire harness 1 has four electric wires 11 to 14, of which two electric wires 11, 12 are covered with the first inner sheath 60 and the other two electric wires 13, 14 are covered with the second inner sheath 70, has been described. However, the number of electric wires may be one to three, or not less than five. In addition, the electric wires may not be covered with an inner sheath.

In the above embodiment, the case where the extending direction of the first cable 6 including the electric wires 11 and 12 and the extending direction of the second cable 7 including the electric wires 13 and 14 are at right angles has been described. However, these extending directions are not limited to being at right angles, and can be adjusted in various ways taking into account the positions relative to the objects to be connected. The same applies to the extending direction of the ground wire 4.

In addition, in the above embodiment, the case where the wire harness 1 is mounted on a vehicle to connect the wheel speed sensor 87 and the variable damping-force damper 83 to the control devices has been described. However, the objects to be connected by the wire harness 1 are not limited thereto. In addition, the wire harness of the invention is not limited to being used for wiring in vehicles, and can also be used for, e.g., industrial machines or equipment, information technology devices, or the like.

1. A wire harness, comprising:
a plurality of electric wires;
a sheath that covers a portion of the plurality of electric wires in a longitudinal direction;
a shield conductor that is interposed between the plurality of electric wires and the sheath and covers all of the plurality of electric wires;
a ground wire connected to the shield conductor; and
a covering body that covers an outer circumference of the shield conductor and the plurality of electric wires extending out of an end of the sheath, as well as the end of the sheath and a portion of the ground wire,
wherein extending directions of the plurality of electric wires and the ground wire from the covering body are fixed by the covering body.

2. The wire harness according to claim 1, wherein the ground wire comprises a ground wire conductor and an insulation covering the ground wire conductor, wherein a portion of the insulation is covered with the covering body on one end side of the ground wire, and wherein the ground wire conductor extends out of the insulation on an other end side of the ground wire.

3. The wire harness according to claim 2, wherein a portion of the shield conductor extending out of the sheath is folded back onto an outer circumference of the sheath inside the covering body, and wherein the ground wire conductor is connected to the folded back portion of the shield conductor.

4. The wire harness according to claim 3, wherein the ground wire conductor is wound around an outer circumference of the folded back portion of the shield conductor.

5. The wire harness according to claim 4, wherein the ground wire conductor comprises a wound portion wound around the outer circumference of the folded back portion of the shield conductor, and a twisted portion twisted together, and wherein the folded back portion of the shield conductor is tightened by the wound portion.

6. The wire harness according to claim 3, wherein the portion of the ground wire conductor is placed on the outer circumference of the folded back portion of the shield conductor, and the portion of the ground wire conductor is fixed to the shield conductor by a fixing member.

7. The wire harness according to claim 1, wherein the covering body comprises a resin molded body or a cover formed by combining a plurality of cover members.

8. The wire harness according to claim 7, wherein a metal bracket is fixed to the covering body.
